(19) United States
(12) Patent Application Publication
(10) Pub. No.: US 2025/0212600 A1
(43) Pub. Date: Jun. 26, 2025

(54) LIGHT EMITTING ELEMENT AND DISPLAY DEVICE INCLUDING THE SAME

(71) Applicant: Samsung Display Co., LTD., Yongin-si (KR)

(72) Inventors: HAKCHOONG LEE, Yongin-si (KR); PILGU KANG, Yongin-si (KR); Dong Chan KIM, Yongin-si (KR); Ji Young MOON, Yongin-si (KR); JONGWON LEE, Yongin-si (KR); Chang-Min LEE, Yongin-si (KR); Jung Ho CHOI, Yongin-si (KR); Jae Hoon HWANG, Yongin-si (KR)

(21) Appl. No.: 18/810,378

(22) Filed: Aug. 20, 2024

(30) Foreign Application Priority Data
Dec. 22, 2023 (KR) 10-2023-0189380

(51) Int. Cl. H10K 50/17; H10K 50/12; H10K 50/13; H10K 50/805; H10K 59/32; H10K 85/60; H10K 102/00

(52) U.S. Cl. CPC H10K 50/171; H10K 50/12; H10K 50/13; H10K 50/805; H10K 59/32; H10K 85/622; H10K 85/633; H10K 85/636; H10K 85/654; H10K 85/6572; H10K 2102/351

(57) ABSTRACT

A light emitting element according to an embodiment includes a first electrode, two or more light emitting units on the first electrode, and a second electrode on the two or more light emitting units, wherein the second electrode includes silver-lithium (Ag—Li), and the light emitting unit at the top of the two or more light emitting units includes ytterbium, and it includes any one selected from an electron injection layer including ytterbium, and an electron injection layer doped with a metal in a compound represented by the following Formula 1.

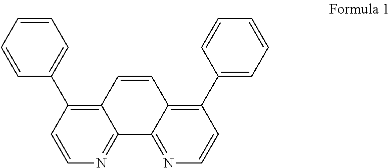 [SMILES: c1ccc(-c2ccnc3c2ccc2c(-c4ccccc4)ccnc23)cc1]

### CROSS-REFERENCE TO RELATED APPLICATION

The present application claims priority to and the benefit of Korean Patent Application No. 10-2023-0189380, filed on Dec. 22, 2023, in the Korean Intellectual Property Office, the entire content of which is hereby incorporated by reference.

### BACKGROUND

### 1. Field

Embodiments of the present disclosure relate to a light emitting element and a display device including the same.

### 2. Description of the Related Art

A light emitting element is a device that converts electrical energy into light energy.

Embodiments of such light emitting elements include organic light emitting elements including organic materials in the light emitting layer, and quantum dot light emitting elements including quantum dots in the light emitting layer.

The light emitting element may include a first electrode and a second electrode that overlap each other, a hole transport region, a light emitting layer, and an electron transport region between them.

Holes injected from the first electrode move to the light emitting layer through the hole transport region, and electrons injected from the second electrode move to the light emitting layer through the electron transport region.

Holes and electrons combine in the light emitting layer area to generate excitons.

Light is generated when excitons change from an excited state to a ground state.

### SUMMARY

Embodiments of the present disclosure improve light emission efficiency and lifespan of a light emitting element and address a pixel shrinkage problem.

A light emitting element according to an embodiment includes a first electrode, two or more light emitting units on the first electrode, and a second electrode on the two or more light emitting units, wherein the second electrode includes silver-lithium (Ag—Li) and the light emitting unit at the top of the two or more light emitting units includes ytterbium, and includes one selected from an electron injection layer consisting of ytterbium and an electron injection layer doped with a metal in a compound represented by the following Formula 1 (e.g., the metal doped in the compound represented by Formula 1 may be a complex or compound including the metal bonded to the nitrogen atoms in the compound represented by Formula 1).

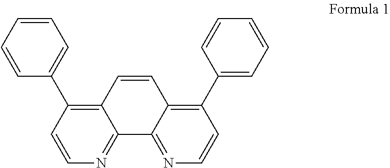 [SMILES: c1ccc(-c2ccnc3c2ccc2c(-c4ccccc4)ccnc23)cc1]

The metal doped in the compound represented by Formula 1 may include Li (e.g., the metal doped in the compound represented by Formula 1 may be a complex or compound including Li bonded to the nitrogen atoms in the compound represented by Formula 1).

Lithium contained in the second electrode may be contained in an amount of 50 vol % or less compared to the second electrode.

The thickness of the second electrode may be 80 angstroms to 140 angstroms.

The second electrode may be a single layer.

The two or more light emitting units may include a first light emitting unit, a second light emitting unit, a third light emitting unit, and a fourth light emitting unit that are sequentially stacked.

The two or more light emitting units may emit different lights (e.g., may emit two or more lights each having a different wavelength).

The first to third light emitting units may emit blue light, and the fourth light emitting unit may emit green light.

The light emitting element according to an embodiment includes a first electrode, two or more light-emitting units on the first electrode, and a second electrode on the two or more light emitting units, and the second electrode includes a first sub-electrode containing silver-magnesium (Ag—Mg), and a second sub-electrode containing silver-lithium (Ag—Li).

The light emitting unit at the top among the two or more light emitting units may include either an electron injection layer made of ytterbium or an electron injection layer doped with a metal in a compound represented by the following Formula 1 (e.g., the metal doped in the compound represented by Formula 1 may be a complex or compound including the metal bonded to the nitrogen atoms in the compound represented by Formula 1).

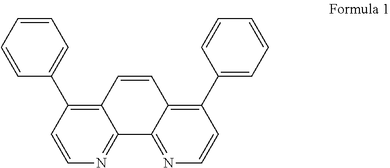 [SMILES: c1ccc(-c2ccnc3c2ccc2c(-c4ccccc4)ccnc23)cc1]

The metal doped in the compound represented by Formula 1 may include Li (e.g., the metal doped in the compound represented by Formula 1 may be a complex or compound including Li bonded to the nitrogen atoms in the compound represented by Formula 1).

The first sub-electrode may include silver and magnesium in a volume ratio of 99:1 to 50:50.

The second sub-electrode may include silver and lithium in a volume ratio of 99:1 to 50:50.

The thickness of the second electrode may be 200 angstroms or less.

A thickness ratio of the first sub-electrode and the second sub-electrode may be 1:9 to 9:1.

The two or more light emitting units may include a first light emitting unit, a second light emitting unit, a third light emitting unit, and a fourth light emitting unit that are sequentially stacked.

The two or more light emitting units may emit different lights (e.g., may emit two or more lights each having a different wavelength).

The first to third light emitting units may emit blue light, and the fourth light emitting unit may emit green light.

A display device according to an embodiment may include the above-described light emitting element.

According to embodiments, it is possible to provide a light emitting device that improves the light emission efficiency and lifespan of the light emitting device and addresses the problem of pixel reduction, and a display device including the same.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 to FIG. 3 are each a cross-sectional view showing a stacked structure of a light emitting element according to an embodiment.

FIG. 4 is an exploded perspective view of a display device according to an embodiment.

FIG. 5 is a schematic cross-sectional view of a display panel according to an embodiment.

FIGS. 6, 7, and 8 show experimental results according to embodiments and comparative examples.

### DETAILED DESCRIPTION

Hereinafter, with reference to the attached drawings, various embodiments of the present disclosure will be described in more detail so that those skilled in the art can easily implement embodiments of the present disclosure.

The subject matter of the present disclosure may be implemented in many different forms and is not limited to the embodiments described herein.

In order to clearly explain the subject matter of the present disclosure, description of parts that are not relevant to the description may be omitted, and identical or similar components are assigned the same reference numerals throughout the specification.

In addition, the size and thickness of each component shown in the drawings may be shown arbitrarily for convenience of explanation, and therefore, the present disclosure is not necessarily limited to that which is shown.

In the drawings, the thickness may be enlarged to clearly express various layers and areas.

In the drawings, for convenience of explanation, the thicknesses of some layers and regions may be exaggerated.

Additionally, when a part of a layer, membrane, region, or plate is said to be “above” or “on” another part, this includes not only cases where it is “directly above” another part, but also cases where there is another part in between.

Conversely, when a part is said to be “on top” of or “directly on” another part, it means that there is no other part in between.

In addition, being “above” or “on” a reference part means being above or below the reference part, and does not necessarily mean being “above” or “on” it in the direction opposite to gravity.

In addition, throughout the specification, when a part is said to “include” a certain component, this means that it may further include other components rather than excluding other components, unless specifically stated to the contrary.

In addition, throughout the specification, when reference is made to “on a plane,” this means when the target portion is viewed from above, and when reference is made to “in a cross-section,” this means when a cross-section of the target portion is cut vertically and viewed from the side.

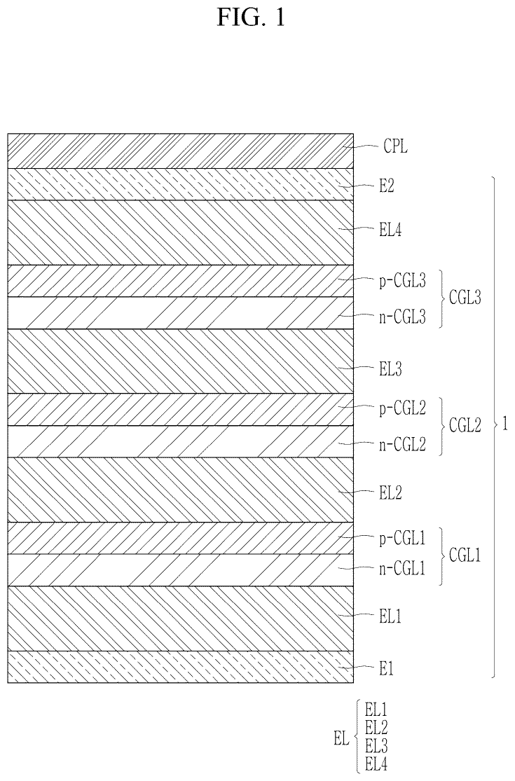

Hereinafter, a light emitting element according to an embodiment will be described with reference to FIGS. 1-3.

FIG. 1 to FIG. 3 each show a stacked structure of a light emitting element according to an embodiment.

Firstly, referring to FIG. 1, the light emitting element 1 may include a first electrode E1, a second electrode E2, and a light emitting unit EL between the first electrode E1 and the second electrode E2.

The light emitting element 1 according to an embodiment may be a top emitting type (or kind).

In this case, the first electrode E1 may be an anode and the second electrode E2 may be a cathode, but the present disclosure is not limited thereto.

The light emitting element 1 according to embodiments of the present disclosure may be a bottom emitting type (or kind).

In this case, the first electrode E1 may be a cathode and the second electrode E2 may be an anode.

In an embodiment, the light emitting element 1 has a reflective first electrode E1 and a second electrode E2 that is either transparent or semi-transparent, so the light emitting element 1 can emit light from the first electrode E1 to the second electrode E2.

Hereinafter, the case where the light emitting element is a top emitting type (or kind) will be described.

The first electrode E1 may be formed, for example, by providing a first electrode material on the upper part of the substrate using a deposition method and/or a sputtering method.

When the first electrode E1 is an anode, the material for the first electrode may be selected from materials having a high work function to facilitate hole injection.

The first electrode E1 may be a reflective electrode, a transflective electrode, or a transmissive electrode.

In order to form the first electrode E1, which may be a transmissive electrode, the first electrode material may be indium tin oxide (ITO), indium zinc oxide (IZO), tin oxide (SnO2), zinc oxide (ZnO), or any of the foregoing, and it may be selected from a combination thereof, but is not limited thereto.

In embodiments, to form the first electrode E1, which may be a transflective electrode or a reflective electrode, the first electrode material may be magnesium (Mg), silver (Ag), aluminum (Al), or aluminum-lithium (Al—Li), calcium (Ca), magnesium-indium (Mg—In), magnesium-silver (Mg—Ag), or any combination thereof, but is not limited thereto.

The first electrode E1 may have a single-layer structure or a multi-layer structure having a plurality of layers.

For example, the first electrode E1 may have a three-layer structure of ITO/Ag/ITO, but is not limited thereto.

A light emitting unit EL is on the first electrode E1.

The light emitting element 1 according to an embodiment may include at least one light emitting unit EL.

In embodiments, the light emitting element 1 may include m light emitting units EL, and m may be a natural number greater than or equal to 2.

Additionally, the light emitting element 1 according to an embodiment may include m−1 charge generation layers CGL1, CGL2, and CGL3 between adjacent light emitting units EL.

The light emitting element 1 according to an embodiment includes a first charge generation layer CGL1 between the first light emitting unit EL1 and the second light emitting unit EL2, a second charge generation layer CGL2 between the second light emitting unit EL2 and the third light emitting unit EL3, and a third charge generation layer CGL3 between the third light emitting unit EL3 and the fourth light emitting unit EL4.

This specification illustrates an embodiment including four light emitting unit EL1, EL2, EL3, EL4 and three charge generation layers CGL1, CGL2, CGL3, but it is not limited to this, and may suitably vary depending on the number of light emitting units EL.

Each charge generation layer CGL1, CGL2, CGL3 comprises an n-type charge generation layer (e.g., n-CGL1, n-CGL2, and n-CGL3, respectively) that provides electrons to the light emitting unit EL and a p-type charge generation layer (e.g., p-CGL1, p-CGL2, and p-CGL3, respectively) that provides holes to the light emitting unit EL.

In embodiments, a buffer layer may be further between respective ones of the n-type charge generation layer n-CGL1, n-CGL2, and n-CGL3 and the p-type charge generation layer p-CGL1, p-CGL2, and p-CGL3.

The charge generation layers CGL1, CGL2, and CGL3 may generate charges (electrons and holes) by forming a complex through an oxidation-reduction reaction when a voltage is applied.

The charge generation layers CGL1, CGL2, and CGL3 may provide the generated charges to the adjacent light emitting unit EL.

The charge generation layers CGL1, CGL2, and CGL3 can double the current efficiency generated in the light emitting unit EL and can play a role in controlling the balance of charges between adjacent light emitting units EL.

The first charge generation layer CGL1 includes a first-n-type charge generation layer n-CGL1 and a first-p-type charge generation layer p-CGL1.

The first-n-type charge generation layer n-CGL1 may be adjacent to the first light emitting unit EL1, and the first-p-type charge generation layer p-CGL1 may be adjacent to the second light emitting unit EL2.

The second charge generation layer CGL2 may include a second-n-type charge generation layer n-CGL2 and a second-p-type charge generation layer p-CGL2.

The second-n-type charge generation layer n-CGL2 is adjacent to the second light emitting unit EL2, and the second-p-type charge generation layer p-CGL2 can be adjacent to the third light emitting unit EL3.

The third charge generation layer CGL3 may include a third-n-type charge generation layer n-CGL3 and a third-p-type charge generation layer p-CGL3.

The third-n type charge generation layer n-CGL3 is adjacent to the third light emitting unit EL3, and the third-p-type charge generation layer p-CGL3 can be adjacent to the fourth light emitting unit EL4.

The second electrode E2 is on the m-th light emitting unit EL.

The second electrode E2 may be a cathode, which is an electron injection electrode.

In embodiments, each light emitting unit EL may include a light emitting layer.

In embodiments, the light emitting unit EL may include at least one selected from a hole transport region and an electron transport region.

The hole transport region may include a hole injection layer, a hole transport layer, an electron blocking layer, or any combination thereof.

The electron transport region may include a hole blocking layer, an electron transport layer, an electron injection layer, or any combination thereof.

The hole transport region can be formed using any suitable methods generally used in the art.

For example, the hole transport layer can be formed using various suitable methods such as vacuum deposition, spin coating, casting, an LB (Langmuir-Blodgett) method, inkjet printing, laser printing, and/or laser-induced thermal imaging (LITI).

The hole injection layer included in the hole transport region may include a hole injection material.

The hole injection material may include phthalocyanine compounds such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris {N,-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/camphor sulfonic acid), PANI/PSS (polyaniline/poly(4-styrenesulfonate)), NPB (N,N′-di(naphthalene-I-yl)-N,N′-diphenyl-benzidine), NPD (N,N′-Di(1-naphthyl)-N,N′-diphenyl-(1,1′-biphenyl)-4,4′-diamine), TPAPEK (polyetherketone containing triphenylamine), 4-Isopropyl-4′-methyldiphenyliodonium [tetrakis(pentafluorophenyl) borate], HAT-CN (dipyrazino[2,3-f: 2′,3′-h] quinoxaline-2,3,6,7,10,11-hexacarbonitrile), etc.

The hole transport layer included in the hole transport region may include a hole transport material.

The hole transport materials may include carbazole-based derivatives such as N-phenylcarbazole, polyvinylcarbazole, fluorene-based derivatives, triphenylamine-based derivatives such as TPD (N,N′-bis(3-methylphenyl)-N,N′-diphenyl-[1,1-biphenyl]-4,4′-diamine), TCTA (4,4′,4″-tris(N-carbazolyl)triphenylamine), NPB (N,N′-di(naphthalene-I-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), CzSi (9-(4-tert-butylphenyl)-3,6-bis(triphenylsilyl)-9H-carbazole), m-MTDATA (4,4′,4″-[tris(3-methylphenyl)phenylamino] triphenylamine), and/or the like.

The thickness of the hole transport region may be from about 100 Å to about 10,000 Å, for example from about 100 Å to about 5000 Å.

For example, the hole injection layer may have a thickness of about 30 Å to about 1000 Å, and the hole transport layer may have a thickness of about 30 Å to about 1000 Å.

When the thicknesses of the hole transport region, the hole injection layer, and the hole transport layer satisfy the ranges described above, suitable or satisfactory hole transport characteristics can be obtained without a substantial increase in driving voltage.

The electron blocking layer is a layer that serves to prevent or reduce leakage of electrons from the electron transport region to the hole transport region.

The thickness of the electron blocking layer may be from about 10 Å to about 1000 Å.

The electronic blocking layer, for example, may include carbazole-based derivatives such as N-phenylcarbazole, polyvinylcarbazole, fluorene-based derivatives, triphenylamine-based derivatives such as TPD (N,N′-bis(3-methylphenyl)-N,N′-diphenyl-[1,1-biphenyl]-4,4′-diamine), TCTA (4,4′,4″-tris(N-carbazolyl)triphenylamine), NPD (N,N′-di(naphthalene-I-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), and/or mCP.

In addition to the previously mentioned materials, the hole transport region may further include a charge generating material to improve conductivity (e.g., electrical conductivity).

The charge generating material may be uniformly or non-uniformly dispersed within the hole transport region.

The charge generating material may be, for example, a p-dopant.

The p-dopant may be one selected from a quinone derivative, a metal oxide, and a cyano group-containing compound, but is not limited thereto.

For example, p-dopants include quinone derivatives such as tetracyanoquinodimethane (TCNQ) and/or 2,3,5,6-tetrafluoro-7,7′, 8, 8′-tetracyanoquinodimethane (F4-TCNQ), and/or metal oxides such as tungsten oxide and/or molybdenum oxide may be included, but are not limited thereto.

Each layer in the electron transport region may be formed using any suitable method generally used in the art.

For example, the electron transport region may be formed using various suitable methods such as vacuum deposition, spin coating, casting, an LB (Langmuir-Blodgett) method, inkjet printing, laser printing, and/or laser induced thermal imaging (LITI).

The electron injection layer included in the electron transport region may include an electron injection material.

Electron injection materials include halide metals such as LiF, NaCl, CsF, RbCl, and/or RbI, lanthanide metals such as Yb, metal oxides such as Li₂O and/or BaO, materials in which an organic host is doped with a metal such as Li and/or LiQ (lithium quinolate) etc. may be used, but are not limited thereto.

The electron injection layer may also be made of a mixture of an electron transport material and an insulating organo metal salt (e.g., an electrically insulating organo metal salt).

Organic metal salts may be materials having an energy band gap of approximately 4 eV or more.

For example, the organometallic salt may include a metal acetate, a metal benzoate, a metal acetoacetate, a metal acetylacetonate, and/or a metal stearate.

The electron transport layer included in the electron transport region may include an electron transport material.

The electron transport material may include a triazine-based compound and/or an anthracene-based compound.

However, the present disclosure is not limited to the above, and the electronic transport material can include, for example, Alq3 (tris(8-hydroxyquinolinato)aluminum), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), Balq (Bis(2-methyl-8-quinolinolato-N1,08)-(1,1′-biphenyl-4-olato)aluminum), Bebq2 (berylliumbis(benzoquinolin-10-olate), ADN (9,10-di(naphthalene-2-yl) anthracene), TSPO1 (diphenyl(4-(triphenylsilyl)phenyl)phosphine oxide), TPM-TAZ (2,4,6-tris(3-(pyrimidin-5-yl)phenyl)-1,3,5-triazine), and/or mixtures thereof.

The thickness of each electron injection layer may be about 1 Å to about 500 Å, or about 3 Å to about 300 Å.

When the thickness of the electron injection layer satisfies the ranges described above, suitable or satisfactory electron injection characteristics can be obtained without a substantial increase in driving voltage.

The thickness of each electron transport layer may be about 100 Å to about 1000 Å, for example, about 150 Å to about 500 Å.

When the thickness of the electron transport layer satisfies the ranges described above, suitable or satisfactory electron transport characteristics can be obtained without a substantial increase in driving voltage.

The hole blocking layer is a layer that prevents or reduces leakage of holes from the hole transport region to the electron transport region.

The thickness of the hole blocking layer may be about 10 Å to about 1000 Å.

Hole blocking layers include, for example, BCP (2,9-dimethyl-4,7-diphenyl-1,10-phenanthroline), Bphen (4,7-diphenyl-1,10-phenanthroline), and/or T2T (2,4-phenanthroline), and/or 6-tri ([1,1′-biphenyl]-3-yl)-1,3,5-triazine), but are not limited thereto.

The light emitting layer may include one or more selected from organic compounds and semiconductor compounds, but is not limited thereto.

When the light emitting layer includes an organic compound, the light emitting element may be referred to as an organic light emitting element.

The organic compound may include a host and a dopant.

The semiconductor compound may include quantum dots, for example, the light emitting element may be a quantum dot light emitting element.

In embodiments, the semiconductor compound may be an organic and/or inorganic perovskite.

The thickness of the light emitting layer may be about 0.1 nm to about 100 nm.

For example, the thickness of the light emitting layer may be 15 nm to 50 nm.

In embodiments, when the light emitting layer emits blue light, the thickness of the blue light emitting layer may be 15 nm to 20 nm, and when the light emitting layer emits green light, the thickness of the green light emitting layer may be 20 nm to 40 nm, and the thickness of the red light emitting layer may be 40 nm to 50 nm.

When the ranges above are satisfied, the light emitting element may exhibit excellent light emitting characteristics without a substantial increase in driving voltage.

The light emitting layer may include a host material and a dopant material.

The light emitting layer may be formed by using a phosphorescent and/or fluorescent material as a dopant in a host material.

The light emitting layer may be formed by including a thermally activated delayed fluorescence TADF dopant in a host material.

In embodiments, the light emitting layer may include a quantum dot material as a light emitting material.

The core of the quantum dot may be selected from group II-VI compounds, group III-V compounds, group IV-VI compounds, group IV elements, group IV compounds, and combinations thereof.

The color of light emitted from the light emitting layer may be determined by the combination of the host material and the dopant material, the type (or kind) of quantum dot material, and the size of the core.

As the host material of the light emitting layer, any suitable materials generally used in the art can be used, and are not particularly limited, but include fluoranthene derivatives, pyrene derivatives, arylacetylene derivatives, anthracene derivatives, and/or fluorene, and may be selected from fluorene derivatives, perylene derivatives, chrysene derivatives, etc.

Example embodiments include pyrene derivatives, perylene derivatives, and/or anthracene derivatives.

As the dopant material for the light emitting layer, any suitable materials generally used in the art can be used, and are not particularly limited, but include styryl derivatives (e.g., 1,4-bis[2-(3-N-ethylcarbazoryl) vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl) vinyl)phenyl)-N-phenylbenzenamine (N-BDAVBi), perylene and its derivatives (e.g., 2, 5, 8, 11-tetra-t-butylperylene (TBP))), pyrene and its derivatives (e.g., 1,1-dipyrene, 1,4-dipyrenylbenzene, 1,4-Bis(N, N-diphenylamino) pyrene), N1,N6-di(naphthalen-2-yl)-N1,N6-diphenylpyrene-1,6-diamine), etc.

The light emitting element 1 according to an embodiment may include light emitting units EL that emit different lights (e.g., lights having different wavelengths from each other).

At least one of the plurality of light emitting units EL may display a first color, and at least one of the remaining light emitting units EL may display a second color.

The first color and the second color may be different from each other.

For example, the light emitting element may include a first light emitting unit EL1, a second light emitting unit EL2, and a third light emitting unit EL that emit blue light, and a fourth light emitting unit EL4 that emits green light.

A capping layer CPL may be on the second electrode E2 according to an embodiment.

The light emitting element 1 described above may include the following materials according to an embodiment, but is not limited thereto.

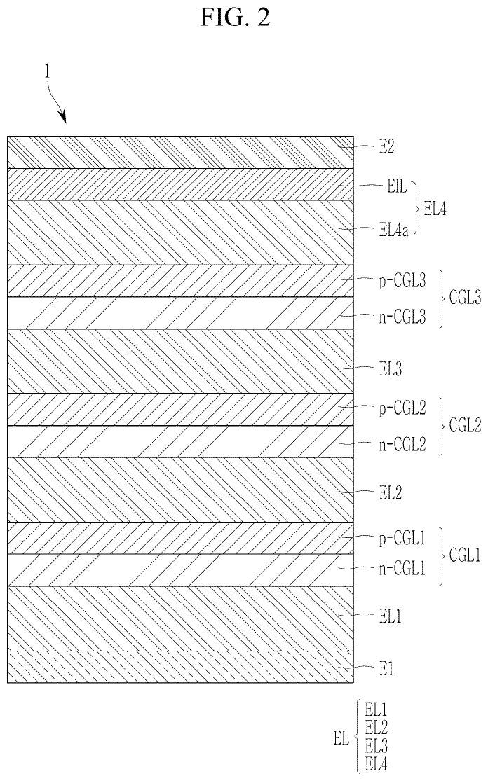

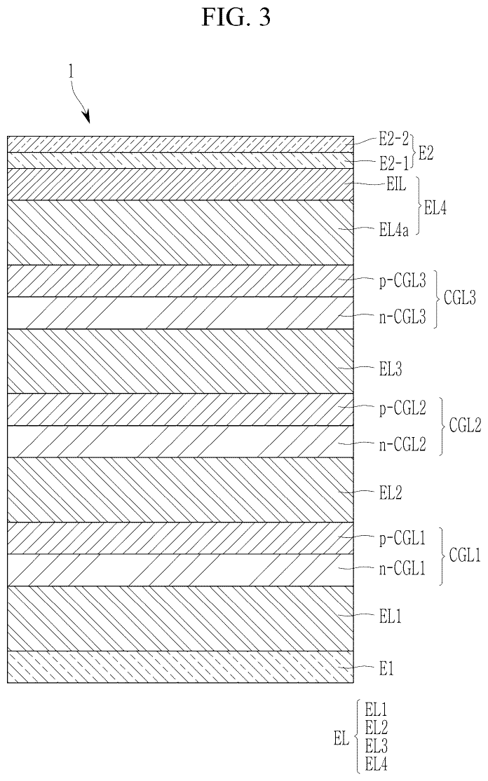

Hereinafter, with reference to FIGS. 2-3, the electron injection layer and the second electrode included in the fourth light emitting unit in the light emitting element according to an embodiment will be described.

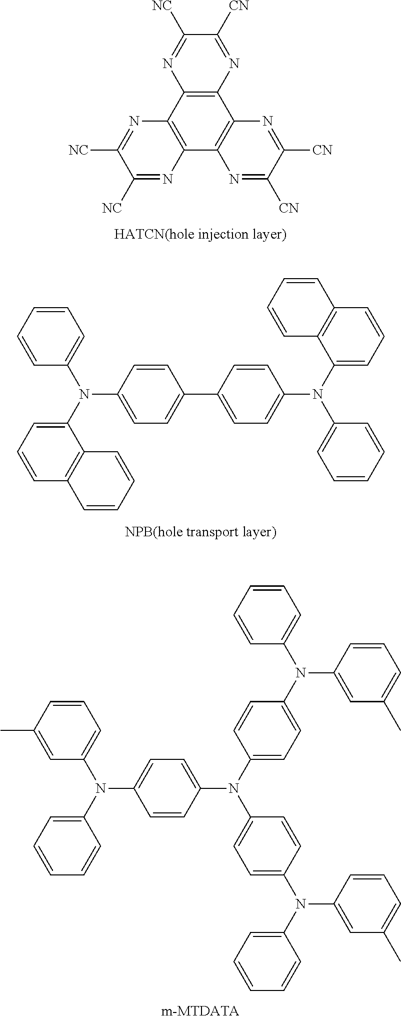

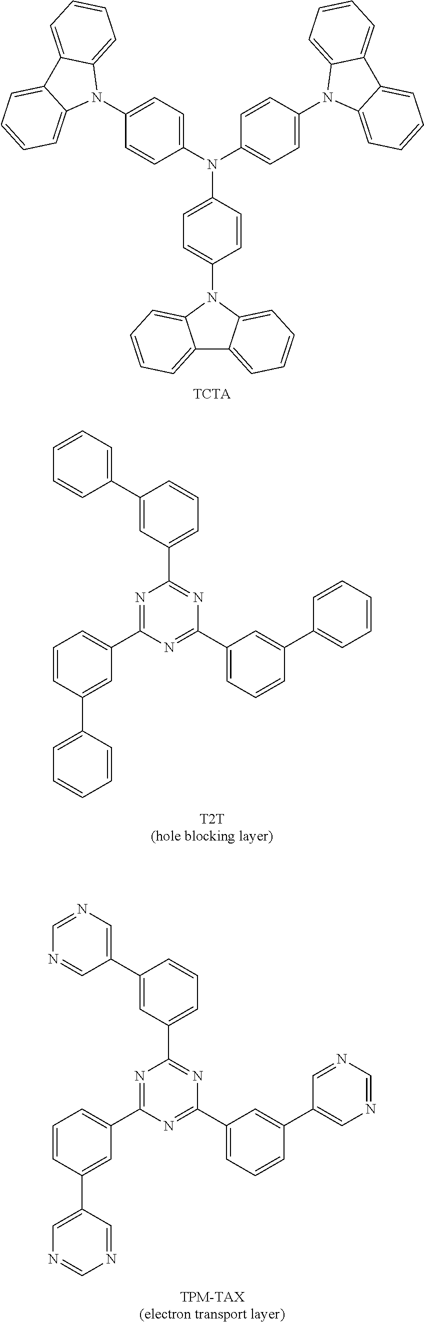 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2cccc(-c3nc(-c4cccc(-c5ccccc5)c4)nc(-c4cccc(-c5ccccc5)c4)n3)c2)cc1 ; c1cc(-c2cncnc2)cc(-c2nc(-c3cccc(-c4cncnc4)c3)nc(-c3cccc(-c4cncnc4)c3)n2)c1]

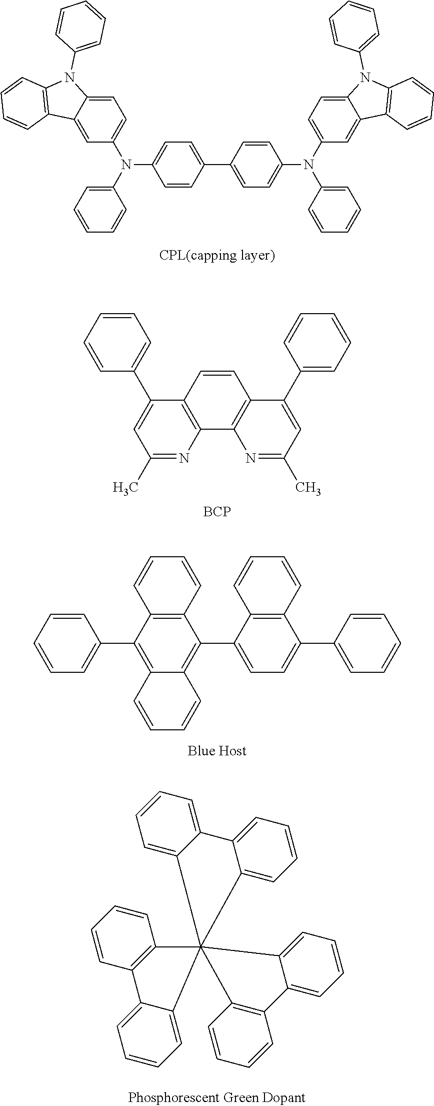

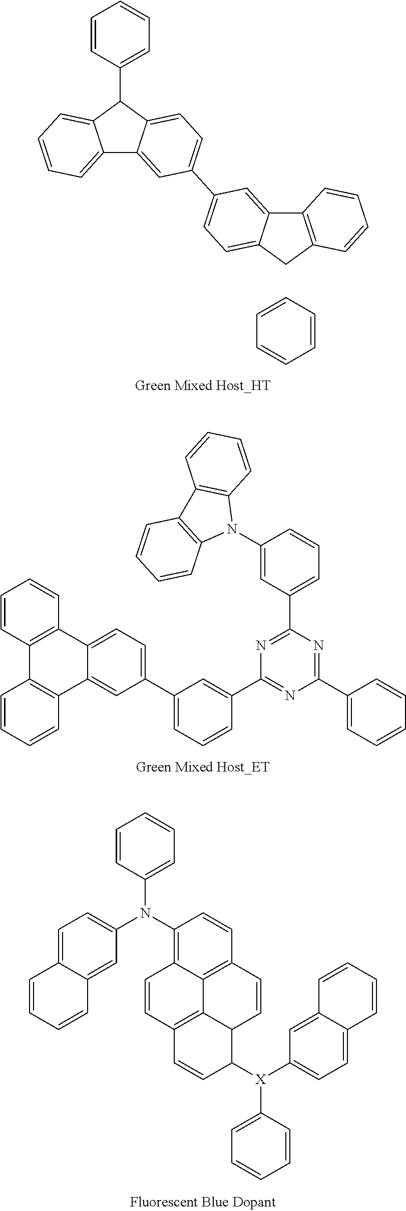

Descriptions of components that are the same as those described above may not be repeated here.

First, referring to FIG. 2, the light emitting element 1 according to an embodiment includes the first electrode E1, a first light emitting unit EL1, a first charge generation layer CGL1, and a second light emitting unit EL2, a second charge generation layer CGL2, a third light emitting unit EL3, a third charge generation layer CGL3, a fourth light emitting unit EL4, and a second electrode E2.

In embodiments, the fourth light emitting unit EL4 may include a hole transport region, a light emitting layer, and an electron transport region.

The first to third light emitting units EL1, EL2, and EL3 according to an embodiment may emit blue light, and the fourth light emitting unit EL4 may emit green light.

In embodiments, the fourth light emitting unit EL4 is shown divided into an electron injection layer EIL and the remaining stacked structure EL4a.

The fourth light emitting unit EL4 may include an electron injection layer EIL include a lanthanide metal, and for example, may include an electron injection layer EIL including ytterbium (Yb).

However, the electron injection layer is not limited to this and may be replaced with a metal having a work function value of less than 3.7 eV.

In embodiments, the fourth light emitting unit EL4 may include an organic compound represented by the following Formula 1 and a metal doped into the organic compound.

In embodiments, the metal doped into the organic compound may be lithium (Li) (e.g., Li may be bonded to the nitrogen atoms in Formula 1).

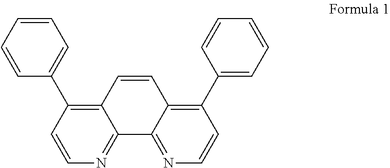 [SMILES: c1ccc(-c2ccnc3c2ccc2c(-c4ccccc4)ccnc23)cc1]

The second electrode E2 may be on the fourth light emitting unit EL4.

The second electrode E2 according to an embodiment may include silver-lithium (Ag—Li).

Lithium (Li) contained in the second electrode E2 may be 50 vol % or less compared to the second electrode E2 (e.g., based on 100 vol % of the second electrode E2).

The second electrode E2 is not limited to the foregoing, and the aforementioned silver (Ag) can be replaced with a metal having electrical conductivity of 1×10⁷ S/m or more, and for example, it may be replaced with gold (Ag), copper (Cu), aluminum (Al), etc.

In embodiments, the lithium (Li) may be replaced with a hygroscopic metal, for example magnesium (Mg), potassium (K), cesium (Cs), rubidium (Rb), calcium (Ca), ytterbium (Yb), and/or samarium (Sm).

The thickness of the second electrode E2 may be 80 angstroms to 140 angstroms.

The light emitting element according to an embodiment may include an electron injection layer EIL including ytterbium (Yb) and a second electrode E2 including silver-lithium (Ag—Li).

In embodiments, the light emitting element according to an embodiment may include an electron injection layer EIL doped with lithium (Li) in an organic material represented by Formula 1 above, and a second electrode E2 including silver-lithium (Ag—Li).

Lithium (Li) contained in the second electrode E2 may serve to collect moisture, thereby preventing or reducing pixel shrinkage.

In embodiments, because the light absorption rate of lithium (Li) is relatively low, luminous efficiency can also be increased.

The light emitting element according to embodiments may have improved luminous efficiency and device lifespan.

Hereinafter, a light emitting element according to an embodiment will be described with reference to FIG. 3.

Description of the same configuration as the light emitting element described above may not be repeated here.

Referring to FIG. 3, the light emitting element 1 according to an embodiment includes the above-described first electrode E1, first light emitting unit EL1, first charge generation layer CGL1, second light emitting unit EL2, a second charge generation layer CGL2, a third light emitting unit EL3, a third charge generation layer CGL3, a fourth light emitting unit EL4, and a second electrode E2.

In embodiments, the fourth light emitting unit EL4 may include the above-described hole transport region, light emitting layer, and electron transport region.

The first to third light emitting units EL1, EL2, and EL3 according to an embodiment may emit blue light, and the fourth light emitting unit EL4 may emit green light.

In embodiments, the fourth light emitting unit EL4 is shown divided into an electron injection layer EIL and the remaining stacked structure EL4a, but the present disclosure is not limited thereto.

The fourth light emitting unit EL4 may include an electron injection layer EIL including a lanthanide metal, and for example, may include an electron injection layer EIL including ytterbium (Yb).

However, the present disclosure is not limited to the above and can be replaced with a metal having a work function value of less than 3.7 eV.

In embodiments, the fourth light emitting unit EL4 may include an organic compound represented by the following Formula 1 and a metal doped into the organic compound (e.g., the metal may be bonded to the nitrogen atoms of Formula 1).

For example, the metal doped into the organic compound may be lithium (Li) (e.g., the lithium may be bonded to the nitrogen atoms of Formula 1).

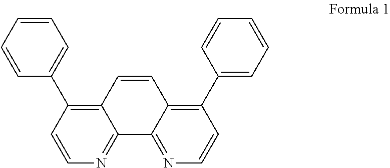 [SMILES: c1ccc(-c2ccnc3c2ccc2c(-c4ccccc4)ccnc23)cc1]

The second electrode E2 according to an embodiment may include a first sub-electrode E2-a and a second sub-electrode E2-b.

The first sub-electrode E2-a may be adjacent to the fourth light emitting unit EL4, and the second sub-electrode E2-b may be on the first sub-electrode E2-a.

The first sub-electrode E2-a may include silver-magnesium (Ag—Mg), and the second sub-electrode E2-b may include silver-lithium (Ag—Li).

The first sub-electrode E2-a may include silver and magnesium in a volume ratio of 99:1 to 50:50.

The second sub-electrode E2-b may include silver and lithium in a volume ratio of 99:1 to 50:50.

The first sub-electrode E2-a is not limited to the above materials, and the silver (Ag) may be replaced with a metal having electrical conductivity of 1×10⁷ S/m or more, for example, gold (Ag), copper (Cu), aluminum (AI), etc.

In embodiments, the magnesium (Mg) included in the first sub-electrode E2-a may be replaced with a metal having a work function value of 3 eV or less, for example, calcium (Ca), lithium (Li), ytterbium (Yb), and/or samarium (Sm).

The second sub-electrode E2-b is also not limited to the above-described materials, and the silver (Ag) may be replaced with a metal having electrical conductivity of 1×10⁷ S/m or more, such as gold (Ag), copper (Cu), aluminum (Al), etc.

In embodiments, the lithium (Li) can be replaced with a hygroscopic metal, for example magnesium (Mg), potassium (K), cesium (Cs), rubidium (Rb), calcium (Ca), ytterbium (Yb), and/or samarium (Sm), and may contain a metal different from the metal included in the first sub-electrode E2-a.

The total thickness of the first sub-electrode E2-a and the second sub-electrode E2-b may be 200 angstroms or less.

The thickness ratio of the first sub-electrode E2-a and the second sub-electrode E2-b may be 1:9 to 9:1.

Lithium (Li) included in the second sub-electrode E2-b may play a role in collecting moisture, thereby preventing or reducing pixel shrinkage.

In embodiments, because the light absorption rate of lithium (Li) is relatively low, luminous efficiency may also be increased.

The light emitting element according to embodiments may have improved luminous efficiency and device lifespan.

When the second electrode E2 is formed only from the first sub-electrode E2-a, magnesium contained in the second electrode has a high light absorption rate, so there is a problem in that light output efficiency is reduced.

Additionally, when the electron injection layer includes an organic host material, there is a problem that magnesium is unable to collect outgassing generated from the electron injection layer, etc., thereby resulting in pixel shrinkage.

However, according to embodiments, the light emitting element includes a second sub-electrode containing silver-lithium, thereby improving the luminous efficiency and lifespan of the light emitting element and reducing pixel shrinkage.

Hereinafter, a display device including the above-described light emitting element will be described.

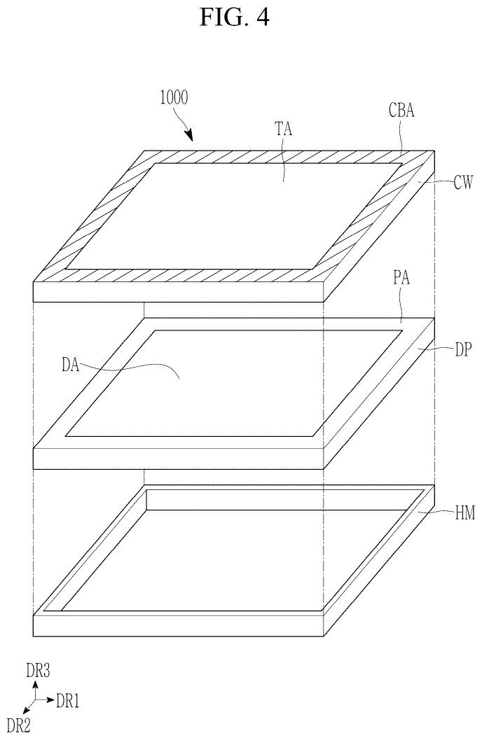

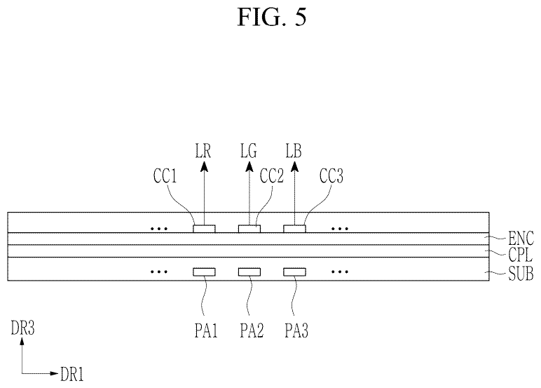

FIG. 4 is an exploded perspective view of a display device according to an embodiment, and FIG. 5 is a schematic cross-sectional view of a display panel according to an embodiment.

First, referring to FIG. 4, a display device according to an embodiment may include a cover window CW, a display panel DP, and a housing HM.

The cover window CW may include an insulating panel (e.g., an electrically insulating panel).

For example, the cover window CW may include glass, plastic, or a combination thereof.

The front of the cover window CW may define the front of the display device 1000.

The transmission area TA may be an optically transparent area.

For example, the transmission area TA may be an area having a visible light transmittance of about 90% or more.

The blocking area CBA may define the shape of the transmission area TA.

The blocking area CBA is adjacent to the transmission area TA and may surround the transmission area TA.

The blocking area CBA may be an area having relatively low light transmittance compared to the transmission area TA.

The blocking area CBA may include an opaque material that blocks light.

The blocking area CBA may have a set or predetermined color.

The blocking area CBA may be defined by a bezel layer provided separately from the transparent substrate defining the transparent area TA, or may be defined by an ink layer formed by inserting and/or coloring the transparent substrate.

A side of the display panel DP on which the image is displayed is parallel to the side defined by the first direction DR1 and the second direction DR2.

The third direction DR3 indicates the normal direction of a side on which the image is displayed, for example, the thickness direction of the display panel DP.

The front (or upper) and back (or lower) surfaces of each member are separated by the third direction DR3.

However, the directions indicated by the first to third directions DR1, DR2, and DR3 are relative concepts and can be converted to other directions.

The display panel DP may be a flat rigid display panel, but is not limited thereto and may be a flexible display panel.

In embodiments, the display panel DP may be include an organic light emitting display panel.

However, the type (or kind) of display panel DP is not limited to this and may include various suitable types (or kinds) of panels.

For example, the display panel DP may include a liquid crystal display panel, an electrophoretic display panel, an electrowetting display panel, etc.

In embodiments, the display panel DP may include a next-generation display panel such as a micro light emitting diode display panel, a quantum dot light emitting diode display panel, and/or a quantum dot organic light emitting diode display panel.

In embodiments, micro LED display panels are including light emitting diodes measuring 10 to 100 micrometers to form each pixel.

These micro light emitting diode display panels have at least the following features: they use inorganic materials, the backlight can be omitted, the response speed is fast, high brightness can be achieved utilizing low power, and it does not break when bent.

Quantum dot light emitting diode display panels may be made by attaching a film containing quantum dots and/or forming them with a material containing quantum dots.

Quantum dots are particles made of inorganic materials such as, for example, indium and cadmium, emit light on their own, and have a diameter of several nanometers or less, but the present disclosure is not limited thereto.

By controlling the particle size of quantum dots, light of a suitable or desired color can be displayed.

Quantum dot organic light emitting diode display panels use blue organic light emitting diodes as a light source, and may be made by attaching a film containing red and green quantum dots on top of it, and/or by depositing a material containing red and green quantum dots to achieve a set or desired color.

The display panel DP according to an embodiment may be made of various suitable other display panels.

As shown in FIG. 4, the display panel DP includes a display area DA where an image is displayed, and a non-display area PA adjacent to the display area DA. The non-display area PA is an area where images are not displayed.

For example, the display area DA may have a square shape, and the non-display area PA may have a shape surrounding the display area DA.

However, the shape of the display area DA and the non-display area PA may be relatively designed without being limited thereto.

The housing HM provides a set or predetermined internal space.

The display panel DP is mounted inside the housing HM.

In addition to the display panel DP, various suitable electronic components, such as a power supply unit, a storage device, and/or an audio input/output module, may be mounted inside the housing HM.

Next, a display panel according to an embodiment will be described with reference to FIG. 5.

Referring to FIGS. 4-5, a plurality of pixels PA1, PA2, and PA3 may be on the substrate SUB corresponding to the display area DA of the display panel DP.

Each pixel PA1, PA2, and PA3 may include a plurality of transistors and a light emitting element connected thereto.

The light emitting element may include the light emitting element previously described with reference to FIGS. 2-3.

The capping layer CPL and encapsulation layer ENC described above may be on the plurality of pixels PA1, PA2, and PA3.

The display area DA may be protected from external air and/or moisture through the encapsulation layer ENC.

The encapsulation layer ENC may be integrally provided to overlap the entire surface of the display area DA, and may be partially on the non-display area PA.

A first color conversion unit CC1, a second color conversion unit CC2, and a transmission unit CC3 may be on the encapsulation layer ENC.

The first color conversion unit CC1 overlaps with the first pixel PA1, the second color conversion unit CC2 overlaps with the second pixel PA2, and the transmission unit CC3 overlaps with the third pixel PA3.

Light emitted from the first pixel PA1 may pass through the first color conversion unit CC1 to provide red light LR.

Light emitted from the second pixel PA2 may pass through the second color conversion unit CC2 to provide green light LG.

Light emitted from the third pixel PA3 may pass through the transmission part CC3 to provide blue light LB.

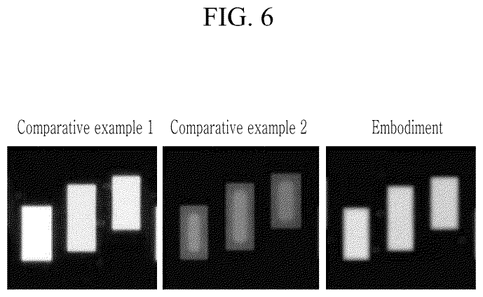

Hereinafter, embodiments and comparative examples will be described with reference to FIGS. 6-8.

FIGS. 6-8 show experimental results according to embodiments and

comparative examples.

Comparative Example 1 of FIG. 6 includes an electron injection layer containing ytterbium (Yb) and a second electrode containing silver-magnesium (Ag—Mg).

In Comparative Example 1, magnesium (Mg) is included at 5 vol % based on the total content of the second electrode.

Comparative Example 2 includes an electron injection layer in which the organic host represented by Formula 1 is doped with lithium (Li) and a second electrode containing silver-magnesium (Ag—Mg).

In Comparative Example 2, magnesium is included at 5 vol % based on the total content of the second electrode.

An embodiment is a case where an electron injection layer includes the organic host represented by Formula 1 doped with lithium (Li) and a second electrode containing silver-lithium (Ag—Li).

In the embodiment, lithium (Li) is included at 10 vol % based on the total content of the second electrode.

Each of the second electrodes according to Comparative Example 1, Comparative Example 2, and the embodiment has a thickness of 100 angstroms.

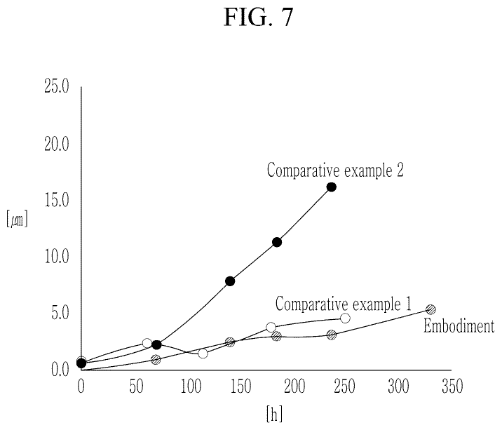

Looking at FIGS. 6-7 together, it can be seen that the pixel reduction phenomenon is significantly reduced in the embodiment compared to Comparative Example 2.

Comparative Example 1 and the embodiment showed similar aspects, but it was confirmed that the pixel shrinkage phenomenon was overall reduced according to the embodiment as compared to Comparative Example 1.

Referring to Table 1 below, Comparative Example 1 is a light emitting element including an electron injection layer including ytterbium and a second electrode including silver-magnesium, and Comparative Example 2 is a light emitting element containing lithium (Li) in the compound represented by Formula 1 above, and this is a light emitting element including a doped electron injection layer and a second electrode made of silver-magnesium.

Embodiment 1 is a light emitting element including an electron injection layer including ytterbium and a second electrode including silver-lithium (Ag—Li).

In Embodiment 1, lithium may be included at 5 vol % based on 100 vol % of the second electrode.

Embodiment 2 is a light emitting element including an electron injection layer including ytterbium and a second electrode including silver-lithium (Ag—Li).

In Embodiment 2, lithium may be included at 10 vol % based on 100 vol % of the second electrode.

Embodiment 3 is a light emitting element including an electron injection layer including ytterbium and a second electrode including silver-lithium (Ag—Li).

In Embodiment 3, lithium may be included at 20 vol % based on 100 vol % of the second electrode.

Embodiment 4 is a light emitting element including an electron injection layer in which lithium is doped into the organic compound represented by Formula 1 above and a second electrode including silver-lithium (Ag—Li).

In Embodiment 4, lithium may be included at 5 vol % based on 100 vol % of the second electrode.

Embodiment 5 is a light emitting element including an electron injection layer in which lithium is doped into the organic compound represented by Formula 1 above and a second electrode including silver-lithium (Ag—Li).

In Embodiment 5, lithium may be included at 10 vol % based on 100 vol % of the second electrode.

Embodiment 6 is a light emitting element including an electron injection layer in which lithium is doped into the organic compound represented by Formula 1 above and a second electrode including silver-lithium (Ag—Li).

In Embodiment 6, lithium may be included at 20 vol % based on 100 vol % of the second electrode.

Referring to Table 1, it was confirmed that the luminous efficiency of Embodiments 1 to 6 was improved from about 3% to a maximum of 15% compared to Comparative Examples 1 and 2.

In addition, it was confirmed that the lifespan of the light emitting element also increased from about 8% to a maximum of 10%.

According to embodiments of the present disclosure, it was confirmed that it is possible to provide a light emitting element that reduces pixel shrinkage while improving luminous efficiency and device lifespan.

TABLE 1

| | | Driving | | |
|---|---|---|---|---|
| | Efficiency | voltage | Luminance | |
| Structure | (Cd/A/y) | (V) | (nit) | Lifespan |
| Comparative Example 1 | 100% | 100% | 1500 | 100% |
| Comparative Example 2 | 108% | 100% | 1500 | 100% |
| Embodiment 1 | 106% | 100% | 1500 | 108% |
| Embodiment 2 | 105% | 100% | 1500 | 109% |
| Embodiment 3 | 103% | 100% | 1500 | 110% |
| Embodiment 4 | 115% | 100% | 1500 | 108% |
| Embodiment 5 | 114% | 100% | 1500 | 109% |
| Embodiment 6 | 112% | 100% | 1500 | 110% |

Referring to Table 2, the comparative example is a light emitting element including a second electrode containing silver-magnesium.

Magnesium is included at 5 vol % based on 100 vol % of the second electrode.

An embodiment is a light emitting element including a second electrode containing silver-lithium.

Lithium is included at up to 20 vol % based on 100 vol % of the second electrode.

According to an embodiment, lithium has lower light absorption compared to magnesium in the entire wavelength range, and thus luminous efficiency can be improved by the second electrode itself.

TABLE 2

Light absorption

| λ | Comparative example | Embodiment |
|---|---|---|
| B | 6.6 | 4.1 |
| 450 nm | | |
| G | 9.1 | 5.8 |
| 540 nm | | |
| R | 11.7 | 8.7 |
| 640 nm | | |

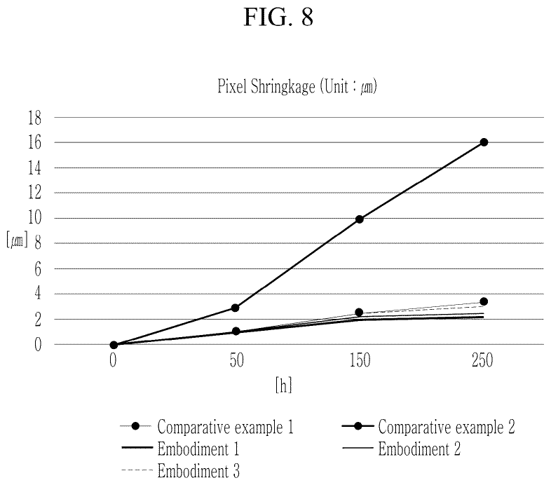

Referring to FIG. 8, Comparative Example 1 is a light emitting element including an electron injection layer including ytterbium (Yb) and a second electrode including silver-magnesium (Ag—Mg), and Comparative Example 2 is a light emitting element having the Formula 1 above, and it is a light emitting element that includes an electron injection layer doped with lithium (Li) in an organic host and a second electrode including silver-magnesium (Ag—Mg).

Embodiment 1 includes a second electrode that includes a first sub-electrode having a thickness of 10 angstroms, which includes silver-magnesium (Ag—Mg), and a second sub-electrode having a thickness of 90 angstroms, which includes silver-lithium (Ag—Li), in an organic host represented by the above Formula 1 with a lithium (Li) doped electron injection layer.

Embodiment 2 includes an electron injection layer doped with lithium (Li) in the organic host represented by the above Formula 1, a first sub-electrode having a thickness of 50 angstroms including silver-magnesium (Ag—Mg), and a second sub-electrode having a thickness of 50 angstroms including silver-lithium (Ag—Li).

Embodiment 3 includes an electron injection layer doped with lithium (Li) in the organic host represented by Formula 1, a first sub-electrode having a thickness of 90 angstroms including silver-magnesium (Ag—Mg), and a second electrode including a second sub-electrode having a thickness of 10 angstroms including silver-lithium (Ag—Li).

In Embodiments 1 to 3, it was confirmed that the pixel reduction shape was significantly reduced compared to Comparative Example 1.

Referring to Table 3 in FIG. 8, it was confirmed that in the embodiments, the light emission efficiency was improved from about 1% to 6%, and the lifespan of the light emitting element was increased by about 3%.

Also, in the embodiments, pixel reduction did not occur.

TABLE 3

| | | Driving | | | Occurrence |
|---|---|---|---|---|---|
| | Efficiency | voltage | Luminance | | of pixel |
| Structure | (Cd/A/y) | (V) | (nit) | Lifespan | reduction |
| Comparative Example | 100% | 100% | 1500 | 100% | ◯ |
| 2 | | | | | |
| Embodiment 1 | 106% | 100% | 1500 | 103% | X |
| Embodiment 2 | 104% | 100% | 1500 | 102% | X |
| Embodiment 3 | 101% | 100% | 1500 | 101% | X |

Referring to Table 4 in FIG. 8, it was confirmed that in the embodiments, the light emission efficiency was improved from about 1% to 5%, and the lifespan of the light emitting element was increased by about 3%.

Also, in the embodiments, pixel reduction did not occur.

TABLE 4

| | | Driving | | | Occurrence |
|---|---|---|---|---|---|
| | Efficiency | voltage | Luminance | | of pixel |
| Structure | (Cd/A/y) | (V) | (nit) | Lifespan | reduction |
| Comparative Example | 100% | 100% | 1500 | 100% | X |
| 1 | | | | | |
| Embodiment 4 | 105% | 100% | 1500 | 103% | X |
| Embodiment 5 | 103% | 100% | 1500 | 102% | X |
| Embodiment 6 | 101% | 100% | 1500 | 101% | X |

According to an embodiment, it was confirmed that it is possible to provide a light emitting element that reduces pixel shrinkage while improving luminous efficiency and device lifespan.

Although example embodiments of the present disclosure have been described above, the scope of the present disclosure is not limited thereto, and various suitable modifications and improvements made by those skilled in the art using the basic concepts of the present disclosure defined in the following claims are also possible.

### DESCRIPTION OF SYMBOLS

EL1, EL2, EL3, EL4: light emitting unit
EIL: electron injection layer
E2: second electrode
E2-a: first sub-electrode
E2-b: second sub-electrode

What is claimed is:

1. A light emitting element, comprising:
a first electrode;
two or more light emitting units on the first electrode; and
a second electrode on the two or more light emitting units,
wherein the second electrode comprises silver-lithium (Ag—Li), and
a light emitting unit at the top among the two or more light emitting units comprises:
any one selected from an electron injection layer comprising ytterbium and an electron injection layer doped with a metal in a compound represented by the following Formula 1:

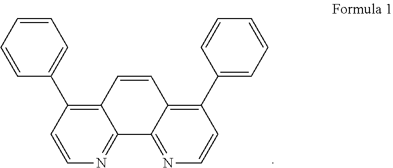 [SMILES: c1ccc(-c2ccnc3c2ccc2c(-c4ccccc4)ccnc23)cc1]

2. The light emitting element of claim 1, wherein:
the metal doped in the compound represented by Formula 1 comprises Li.

3. The light emitting element of claim 1, wherein:
the lithium contained in the second electrode is contained in an amount of 50 vol % or less based on 100 vol % of the second electrode.

4. The light emitting element of claim 1, wherein:
the second electrode has a thickness of 80 angstroms to 140 angstroms.

5. The light emitting element of claim 1, wherein:
the second electrode is a single layer.

6. The light emitting element of claim 1, wherein:
the two or more light emitting units comprise a first light emitting unit, a second light emitting unit, a third light emitting unit, and a fourth light emitting unit sequentially stacked.

7. The light emitting element of claim 6, wherein:
the two or more light emitting units emit different lights.

8. The light emitting element of claim 6, wherein:
the first to third light emitting units emit blue light, and
the fourth light emitting unit emits green light.

9. A display device, comprising:
the light emitting element of claim 1.

10. A light emitting element, comprising:
a first electrode;
two or more light emitting units on the first electrode; and
a second electrode on the two or more light emitting units,
wherein the second electrode comprises:
a first sub-electrode comprising silver-magnesium (Ag—Mg), and
a second sub-electrode comprising silver-lithium (Ag—Li).

11. The light emitting element of claim 10, wherein:
the light emitting unit at the top among the two or more light emitting units comprises:
any one selected from an electron injection layer comprising ytterbium and an electron injection layer doped with a metal in a compound represented by the following Formula 1:

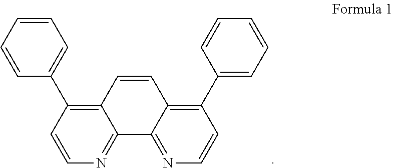 [SMILES: c1ccc(-c2ccnc3c2ccc2c(-c4ccccc4)ccnc23)cc1]

12. The light emitting element of claim 11, wherein:
the metal doped in the compound represented by Formula 1 comprises Li.

13. The light emitting element of claim 11, wherein:
the first sub-electrode comprises silver and magnesium in a volume ratio of 99:1 to 50:50.

14. The light emitting element of claim 11, wherein:
the second sub-electrode comprises silver and lithium in a volume ratio of 99:1 to 50:50.

15. The light emitting element of claim 10, wherein:
the second electrode has a thickness of 200 angstroms or less.

16. The light emitting element of claim 15, wherein:
a thickness ratio of the first sub-electrode and the second sub-electrode is 1:9 to 9:1.

17. The light emitting element of claim 11, wherein:
the two or more light emitting units comprise a first light emitting unit, a second light emitting unit, a third light emitting unit, and a fourth light emitting unit sequentially stacked.

18. The light emitting element of claim 17, wherein:
the two or more light emitting units emit different lights.

19. The light emitting element of claim 18, wherein:
the first to third light emitting units emit blue light, and
the fourth light emitting unit emits green light.

20. A display device, comprising:
the light emitting element of claim 10.
